(19) United States
(12) Patent Application Publication
(10) Pub. No.: US 2026/0304651 A1
(43) Pub. Date: Oct. 1, 2026

(54) HOUSING ASSEMBLY

(71) Applicant: Delta Electronics, Inc., Taoyuan City (TW)

(72) Inventors: Yan-Fong Cheng, Taoyuan City (TW); Chien-Feng Chuang, Taoyuan City (TW)

(21) Appl. No.: 19/191,119

(22) Filed: Apr. 28, 2025

(30) Foreign Application Priority Data
Mar. 25, 2025 (CN) 202510355868.1

(51) Int. Cl. H05K 5/02; H05K 5/13; H05K 7/14

(52) U.S. Cl. CPC H05K 5/0221; H05K 5/13; H05K 7/1432

(57) ABSTRACT

The present disclosure provides a housing assembly. The housing assembly includes a first housing and a second housing. The first housing includes a first sidewall and at least two hook members. Each hook member includes a bending portion and a buckle portion connected to the bending portion. Second parts of the buckle portions of the at least two hook members are extended toward opposite directions, respectively. The second housing includes a bottom plate, a lateral plate and at least two openings. The lateral plate is perpendicularly extended from the bottom plate. Each opening penetrates through the bottom plate and the lateral plate and includes a bottom plate opening, a lateral plate opening and a blocking portion. The hook members of the first housing penetrate through the corresponding openings of the second housing, and the hook members are disposed corresponding to the blocking portions, so as to form a latched state.

### CROSS-REFERENCE TO RELATED APPLICATION

This application claims priority to China Patent Application No. 202510355868.1, filed on Mar. 25, 2025. The entirety of the above-mentioned patent application is incorporated herein by reference for all purposes.

### FIELD OF THE INVENTION

The present disclosure relates to a housing, and more particularly to a housing assembly for a power supply unit.

### BACKGROUND OF THE INVENTION

Typically, a power supply unit (PSU) includes a housing and a circuit board assembly. The housing has an internal accommodating space, and the circuit board assembly includes a circuit board and electronic members and is disposed in the internal accommodating space of the housing. The housing includes a base and a cover. The cover is usually fixed to the base by screwing to achieve the assembly of the housing.

In some power supply units, the housings further include hooks and fixing holes. The hooks are disposed on the cover, and the fixing holes penetrate through the base. The hooks of the cover are plugged into the fixing holes of the base, so that the cover is connected to the base to achieve the assembly of the housing. Generally speaking, the width of the fixing hole is greater than the width of the hook for allowing the hook to engage with the fixing hole. However, due to the larger width of the fixing hole, the hook may slide within the fixing hole, which cause deformation of the hook during assembly and damage to the housing.

Therefore, there is a need of providing a housing assembly to obviate the drawbacks encountered from the prior arts.

### SUMMARY OF THE INVENTION

It is an objective of the present disclosure to provide a housing assembly, which can address the issues encountered from the prior arts and achieve the advantages of preventing the housing components from falling off, reducing the risk of damage or deformation to the hook members and improving the stability and convenience of the assembly structure.

In accordance with an aspect of the present disclosure, there is provided a housing assembly. The housing assembly includes a first housing and a second housing. The first housing includes a first sidewall, at least two hook members, a top plate and a first fixing unit. The first sidewall has a first sidewall outer surface and a first sidewall inner surface opposite to each other. Each of the at least two hook members includes a bending portion and a buckle portion. The bending portion is formed by bending the first sidewall in a direction perpendicular to the first sidewall inner surface. The buckle portion is in connection with an end of the bending portion, and includes a first part and a second part. The first part is in connection with the bending portion. The second part is extending from the first part in a direction parallel to the first sidewall outer surface, and is misaligned with the bending portion. The second parts of the buckle portions of the at least two hook members are extended toward opposite directions, respectively. The top plate is in connection with a side of the first sidewall opposite to the at least two hook members and perpendicular to the first sidewall inner surface. The first fixing unit is disposed on the top plate. The second housing is configured to assemble with the first housing and includes a bottom plate, a lateral plate, at least two openings, a second sidewall and a second fixing unit. The lateral plate is extending from the bottom plate in a direction perpendicular to the bottom plate. Each of the at least two openings includes a bottom plate opening and a lateral plate opening. The bottom plate opening penetrates through the bottom plate. The lateral plate opening penetrates through the lateral plate and is in communication with the bottom plate opening. The width of the bottom plate opening is greater than the width of the lateral plate opening. A blocking portion is formed on a misaligned position of the bottom plate opening and the lateral plate opening. The second sidewall is connected to a side of the bottom plate opposite to the lateral plate. The second fixing unit is disposed on the second sidewall and configured to align and assemble with the first fixing unit for securing. Each of the at least two hook members of the first housing penetrates through corresponding one of the bottom plate openings, the bending portion is accommodated in the lateral plate opening, the second part of each of the at least two hook member is disposed corresponding to the blocking portion, and the first fixing unit and the second fixing unit are aligned and assembled to form a latched state.

The above contents of the present disclosure will become more readily apparent to those ordinarily skilled in the art after reviewing the following detailed description and accompanying drawings, in which:

### BRIEF DESCRIPTION OF THE DRAWINGS

FIG. 1 is a schematic perspective view illustrating a housing assembly according to a first embodiment of the present disclosure;

FIG. 2 is an exploded view illustrating the housing assembly of FIG. 1;

FIG. 3 is a partially enlarged view illustrating an area A of a first housing of the housing assembly of FIG. 2;

FIG. 4 is a partially enlarged view illustrating an area B of a first housing of the housing assembly of FIG. 2;

FIG. 5 is a partially enlarged view illustrating an area C of the housing assembly of FIG. 1;

FIG. 6 is a cross-sectional view of the housing assembly of FIG. 2, wherein the first housing and the second housing are in a disassembled state;

FIG. 7 is a cross-sectional view of the housing assembly of FIG. 2, wherein a buckle portion of a hook member of the first housing is disposed within the bottom plate opening of the second housing;

FIG. 8 is a cross-sectional view of the housing assembly of FIG. 1, wherein the first housing and the second housing are in a latched state;

FIG. 9 is a cross-sectional view of a housing assembly according to a variant embodiment, wherein the first housing and the second housing are in a disassembled state, and an angle between a first sidewall of the first housing and a bottom plate of the second housing is greater than 90 degrees;

FIG. 10 is a cross-sectional view of the housing assembly of FIG. 9, wherein a buckle portion of the first housing penetrates through a bottom plate opening of the second housing; and

FIG. 11 is a cross-sectional view of the housing assembly of FIG. 9, wherein the first housing and the second housing are in a latched state.

### DETAILED DESCRIPTION OF THE PREFERRED EMBODIMENT

The present disclosure will now be described more specifically with reference to the following embodiments. It is to be noted that the following descriptions of preferred embodiments of this disclosure are presented herein for purpose of illustration and description only. It is not intended to be exhaustive or to be limited to the precise form disclosed. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed. Further, spatially relative terms, such as “upper,” “lower,” “front,” “rear,” “top,” “bottom,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. When an element is referred to as being “connected,” or “coupled,” to another element, it can be directly connected or coupled to the other element or intervening elements may be present. Although the wide numerical ranges and parameters of the present disclosure are approximations, numerical values are set forth in the specific examples as precisely as possible. In addition, although the “first,” “second” and the like terms in the claims be used to describe the various elements can be appreciated, these elements should not be limited by these terms, and these elements are described in the respective embodiments are used to express the different reference numerals, these terms are only used to distinguish one element from another element. For example, a first element could be termed a second element, and, similarly, a second element could be termed a first element, without departing from the scope of example embodiments. Besides, “and/or” and the like may be used herein for including any or all combinations of one or more of the associated listed items.

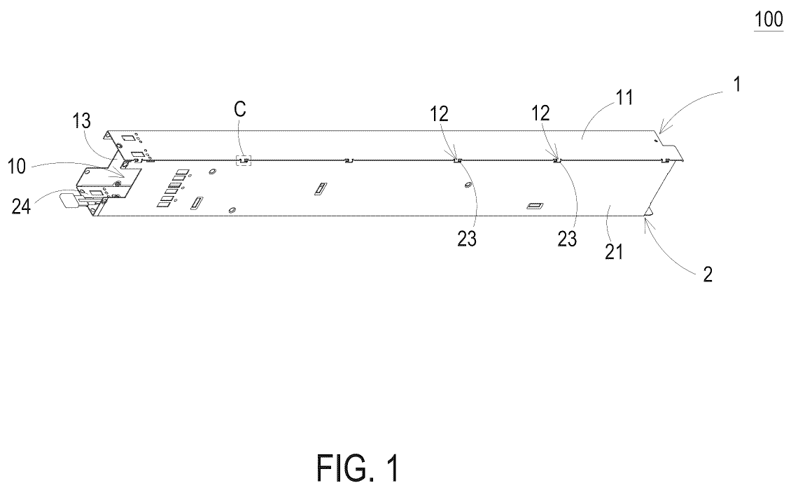

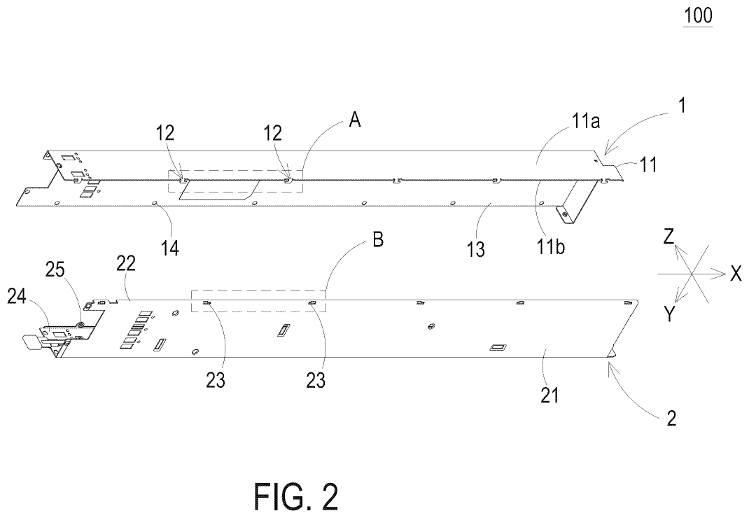

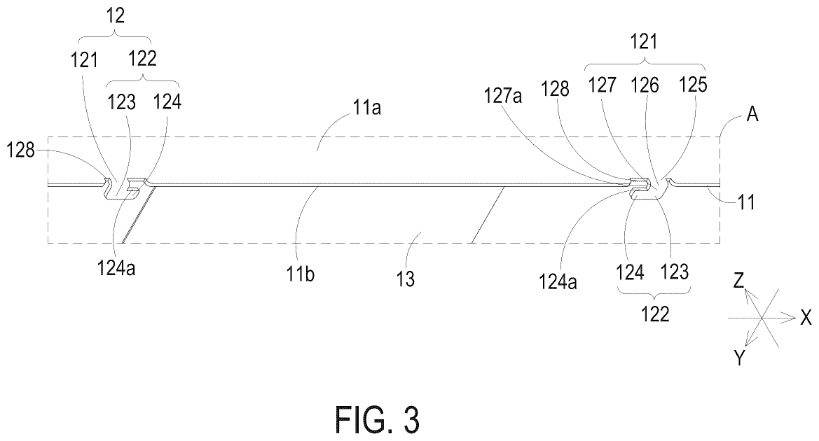

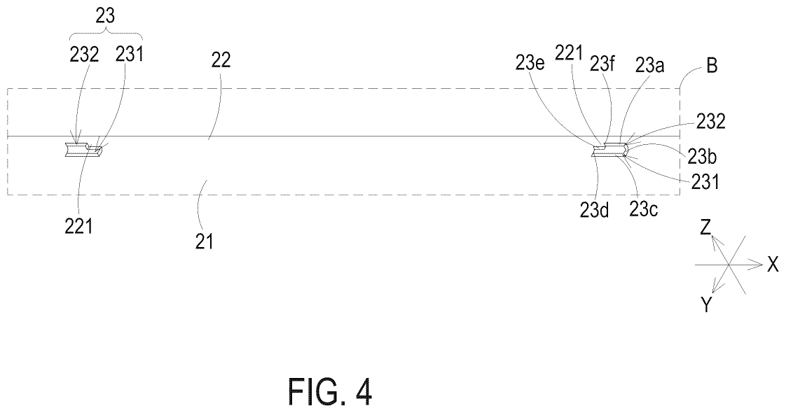

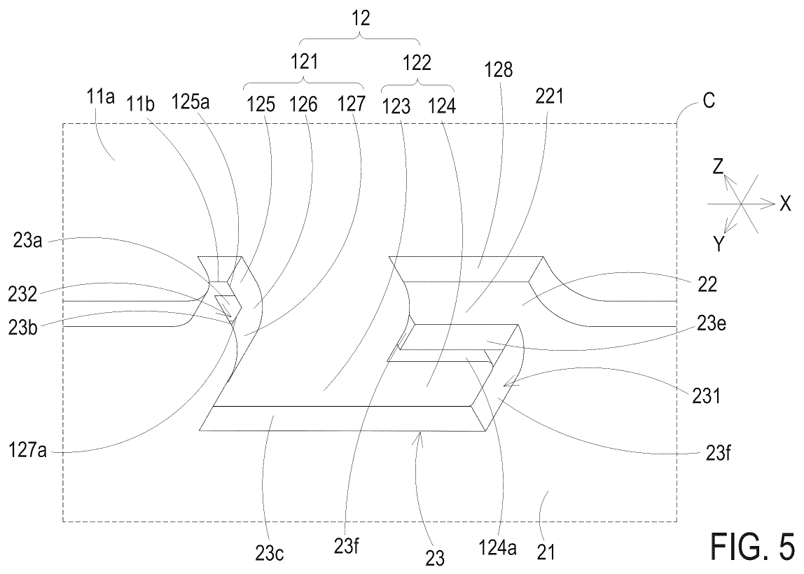

FIG. 1 is a schematic perspective view illustrating a housing assembly according to a first embodiment of the present disclosure, FIG. 2 is an exploded view illustrating the housing assembly of FIG. 1, FIG. 3 is a partially enlarged view illustrating an area A of a first housing of the housing assembly of FIG. 2, FIG. 4 is a partially enlarged view illustrating an area B of a first housing of the housing assembly of FIG. 2, and FIG. 5 is a partially enlarged view illustrating an area C of the housing assembly of FIG. 1. Please refer to FIG. 1 to FIG. 5, in the present embodiment, the housing assembly 100 is applicable to a power supply unit (not shown), but not limited thereto. The housing assembly 100 includes a first housing 1 and a second housing 2. The first housing 1 includes a first sidewall 11, at least two hook members 12, a top plate 13 and a first fixing unit 14. The first sidewall 11 has a first sidewall outer surface 11a and a first sidewall inner surface 11b. The first sidewall outer surface 11a and the first sidewall inner surface 11b are parallel to the XZ plane, respectively. The first sidewall inner surface 11b and the first sidewall outer surface 11a are disposed on two opposite sides of the first sidewall 11. The at least two hook members 12 are spaced apart from each other. Each of the hook members 12 includes a bending portion 121 and a buckle portion 122. The bending portion 121 is formed by bending a portion of the first sidewall 11 in a direction perpendicular to the first sidewall inner surface 11b. In other words, the bending portion 121 is formed by bending from the first sidewall outer surface 11a in the Y-axis direction. The buckle portion 122 is in connection with an end of the bending portion 121, and includes a first part 123 and a second part 124. The first part 123 is in connection with the bending portion 121, and is extending from the bending portion 121 in the Y-axis direction. The second part 124 is extending from the first part 123 in a direction parallel to the first sidewall outer surface 11a (i.e., parallel to the XZ plane), and is misaligned with the bent portion 121. The top plate 13 is in connection with a fist side edge of the first sidewall 11 opposite to the at least two hook members 12. The top plate 13 is perpendicular to the first sidewall inner surface 11b of the first sidewall 11 and parallel to the XY plane. The first fixing unit 14 is disposed on the top plate 13. The second parts 124 of the buckle portions 122 of the at least two hook members 12 are extended toward opposite directions, respectively. As shown in FIG. 1, FIG. 2, FIG. 4 and FIG. 5, the second housing 2 is configured to assemble with the first housing 1, and includes a bottom plate 21, a lateral plate 22, at least two openings 23, a second sidewall 24 and a second fixing unit 25. The bottom plate 21 is parallel to the XY plane. The lateral plate 22 is extending from one side edge of the bottom plate 21 in a direction perpendicular to the bottom plate 21 and is parallel to the XZ plane. Each of the openings 23 includes a bottom plate opening 231 and a lateral plate opening 232. The bottom plate opening 231 penetrates through the bottom plate 21. The lateral plate opening 232 penetrates through the lateral plate 22, and is in communication with the bottom plate opening 231. The width of the bottom plate opening 231 is greater than the width of the lateral plate opening 232. A blocking portion 221 is formed on a misaligned position of the bottom plate opening 231 and the lateral plate opening 232. As shown in FIG. 2, the second sidewall 24 is perpendicularly connected to the other side edge of the bottom plate 21 opposite to the lateral plate 22, and is parallel to the XZ plane. The second fixing unit 25 is disposed on the second sidewall 24, and configured to align and assemble with the first fixing unit 14 of the first housing 1 for securing. In the present embodiment, preferably but not exclusively, the first fixing unit 14 and the second fixing unit 25 are screw holes. In the present embodiment, the housing assembly 100 further includes at least one fixing component (not shown). The fixing component is configured to penetrate through the first fixing unit 14 and the second fixing unit 25, so that the first fixing unit 14 and the second fixing unit 25 are secured to each other. Preferably but not exclusively, the fixing component is a screw.

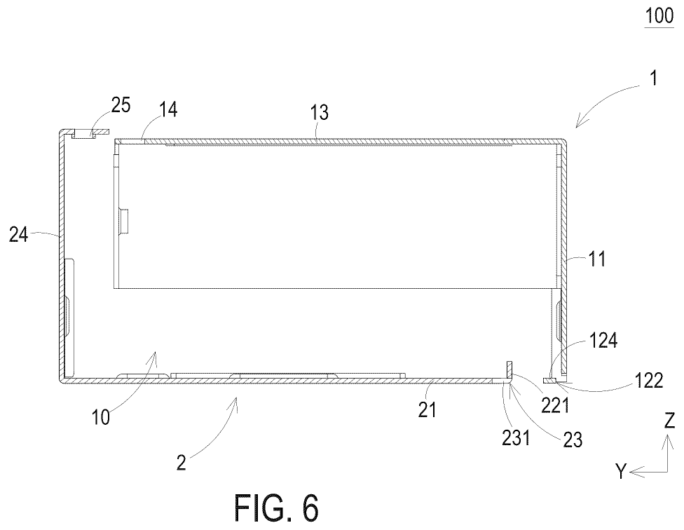

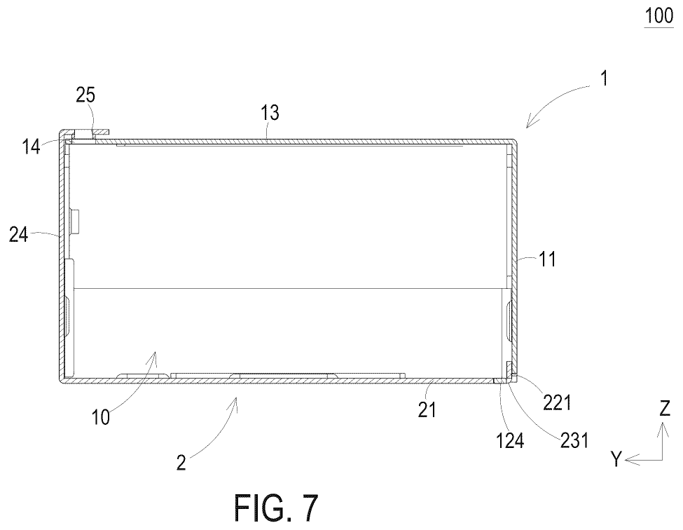

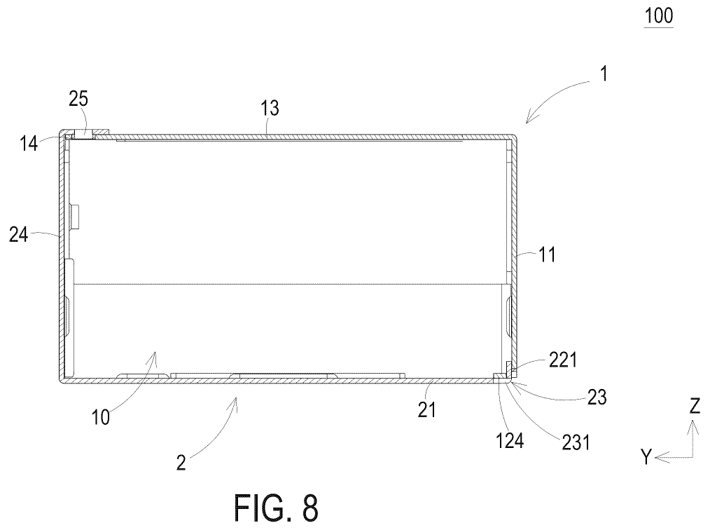

FIG. 6 is a cross-sectional view of the housing assembly of FIG. 2, wherein the first housing and the second housing are in a disassembled state. FIG. 7 is a cross-sectional view of the housing assembly of FIG. 2, wherein the buckle portion of the hook member of the first housing is disposed within the bottom plate opening of the second housing. FIG. 8 is a cross-sectional view of the housing assembly of FIG. 1, wherein the first housing and the second housing are in a latched state. In the present embodiment, the first housing 1 and the second housing 2 are configured to be in one of a latched state and a disassembled state. As shown in FIG. 2 and FIG. 6, the first housing 1 is spaced apart from the second housing 2, in other words, the first housing 1 and the second housing 2 are in the disassembled state. When the first housing 1 and the second housing 2 are switched from the disassembled state to the latched state, the first housing 1 shown in FIG. 6 is moved toward the second housing 2 (along the Y-axis direction), so that the buckle portion 122 of each hook member 12 of the first housing 1 is disposed within the corresponding one of the bottom plate openings 231 of the openings 23 of the second housing 2, as shown in FIG. 7. The first housing 1 shown in FIG. 7 moves in an extension direction parallel to the lateral plate 22 of the second housing 2 (along the Z-axis direction), so that the buckle portion 122 of each hook member 12 of the first housing 1 penetrates through corresponding one of the bottom plate openings 231, and is disposed corresponding to the blocking portion 221. The bending portion 121 is accommodated in the corresponding lateral plate opening 232 (as shown in FIG. 5). The first fixing unit 14 and the second fixing unit 25 are aligned and assembled to form the latched state, as shown in FIG. 1, FIG. 5 and FIG. 8. Since the two hook members 12 of the first housing 1 are plugged along the Y-axis direction into the bottom plate openings 231 of the corresponding openings 23 of the second housing 2, respectively, and the second parts 124 of the buckle portions 122 of the two hook members 12 are extended toward opposite directions, respectively, the movement ranges of the hook members 12 in the X-axis direction can be limited by the bottom plate openings 231. Consequently, before the first housing 1 moves in the direction toward the lateral plate 22 of the second housing 2 (along the Z-axis direction, as shown in FIG. 7), the first fixing unit 14 and the second fixing unit 25 are not aligned, so that the fixing component (i.e., screw) cannot be fastened therein. As a result, the hook members 12 of the first housing 1 and the openings 23 of the second housing 2 would not be damaged due to forced fastening by the user, thereby reducing the risk of damage or deformation to the first housing 1 and the second housing 2.

In an embodiment, the first housing 1 and the second housing 2 are switched from the latched state to the disassembled state. By moving the first housing 1 shown in FIG. 8 in a direction away from the lateral plate 22 of the second housing 2 (along the Z-axis direction), the buckle portion 122 of each hook member 12 of the first housing 1 is disposed in the bottom plate opening 231, as shown in FIG. 7. Thereafter, by moving the first housing 1 shown in FIG. 7 in a direction away from the bottom plate 21 of the second housing 2 (along the Y-axis direction), the buckle portion 122 of each hook member 12 of the first housing 1 is separated from the corresponding bottom plate opening 231 of the second housing 2, and the first housing 1 and the second housing 2 are in the disassembled state, as shown in FIG. 6.

Please refer to FIG. 1 to FIG. 5. In the present embodiment, the bending portion 121 of each hook member 12 includes a first connection segment 125, a bending segment 126 and a second connection segment 127. As shown in FIG. 5, the first connection segment 125 is extending from the first sidewall 11 in a direction parallel to the first sidewall outer surface 11a. An end of the bending segment 126 is in connection with the first connection segment 125, and the other end of the bending segment 126 is bending from a direction parallel to the first sidewall outer surface 11a toward a direction perpendicular to the first sidewall outer surface 11a. An end of the second connection segment 127 is in connection with an end of the bending segment 126 opposite to the first connection segment 125. The second connection segment 127 is extending in a direction perpendicular to the first sidewall outer surface 11a. The other end of the second connection segment 127 is in connection with the first part 123 of the buckle portion 122. The second connection segment 127 of the hook member 12 detachably matches with the corresponding lateral plate opening 232 of the opening 23. By arranging the second connection segment 127 of the hook member 12 to match with the lateral plate opening 232, the sliding range of the second connecting section 127 in the X-axis direction is limited by the lateral plate opening 232 so as to prevent the first housing 1 from sliding relative to the second housing 2. In an embodiment, the width of the lateral plate opening 232 is greater than the width of the second connection segment 127 of the hook member 12, and the difference between the width of the lateral plate opening 232 and the width of the second connection segment 127 is between 0.5 millimeters and 1.5 millimeters. Preferably but not exclusively, the difference between the width of the lateral plate opening 232 and the width of the second connection segment 127 is 1 millimeter (mm).

Please refer to FIG. 4 and FIG. 5 again. In the present embodiment, each of the openings 23 of the second housing 2 includes an opening top surface 23a, a first opening lateral surface 23b, an opening bottom surface 23c, a second opening lateral surface 23d, a blocking portion bottom surface 23e and a blocking portion lateral surface 23f. The opening top surface 23a, the first opening lateral surface 23b, the opening bottom surface 23c, the second opening lateral surface 23d, the blocking portion bottom surface 23e and the blocking portion lateral surface 23f of each opening 23 are sequentially connected, and surround the opening 23. The blocking portion lateral surface 23f, the opening top surface 23a and a part of the first opening lateral surface 23b of each opening 23 surround the lateral plate opening 232. A part of the first opening lateral surface 23b, the opening bottom surface 23c, the second opening lateral surface 23d and the blocking portion bottom surface 23e of each opening 23 surround the bottom plate opening 231. The second connection segment 127 of the bending portion 121 of each hook member 12 is disposed between the first opening lateral surface 23b and the blocking portion lateral surface 23f. The width of the second connection segment 127 is less than the distance between the first opening lateral surface 23b and the blocking portion lateral surface 23f. In an embodiment, the distance between the first opening lateral surface 23b and the blocking portion lateral surface 23f is greater than the width of the second connection segment 127, and a difference therebetween is ranging from 0.5 millimeters and 1.5 millimeters, and 1 millimeter is preferable, but not limited thereto. The sliding range of the second connecting section 127 is limited by the lateral plate opening 232 so as to prevent the first housing 1 from sliding relative to the second housing 2.

Please refer to FIG. 3 to FIG. 5 again. In the present embodiment, the first connection segment 125 of the bending portion 121 of each hook member 12 has a first connection segment inner surface 125a. The first connection segment inner surface 125a of the first connection segment 125 is in connection between the first sidewall inner surface 11b and the bending segment 126. Preferably, the first connection segment inner surface 125a and the first sidewall inner surface 11b are coplanar. The first connection segment inner surface 125a and a part of the first sidewall inner surface 11b are in contact with the lateral plate 22. The second part 124 of the buckle portion 122 of each hook member 12 has a second part lateral surface 124a. The second part lateral surface 124a of the second part 124 is in connection with the second connection segment 127 of the bending portion 121, and is parallel to the first sidewall inner surface 11b. As shown in FIG. 5, the second part lateral surface 124a is in contact with the blocking portion 221 of the lateral plate 22. By arranging the lateral plate 22 between the second part lateral surface 124a and the first sidewall inner surface 11b (including the first connection segment inner surface 125a), the movement range of the lateral plate 22 in the Y-axis direction is limited so as to prevent the first housing 1 from sliding relative to the second housing 2.

Please refer to FIG. 2, FIG. 3 and FIG. 5 again. In the present embodiment, the at least two hook members 12 and the first sidewall 11 are integrally formed into one piece bent structure. The first sidewall 11 includes at least two recesses 128. The at least two recesses 128 are inwardly recessed from the second side edge of the first sidewall 11, respectively, and each hook member 12 is connection with corresponding one of the recesses 128. Since the recesses 128 are inwardly recessed from the second side edge of the first sidewall 11, the waste material generated during the manufacturing process is reduced.

Please refer to FIG. 1, FIG. 2 and FIG. 6 again. In the present embodiment, when the first housing 1 and the second housing 2 are in the latched state, the top plate 13 of the first housing 1 is in contact with the second sidewall 24 of the second housing 2, so that the top plate 13, the first sidewall 11, the bottom plate 21 and the second sidewall 24 collectively define an accommodation space 10. The accommodation space 10 is configured to accommodate a circuit board assembly of the power supply unit, but not limited thereto.

In an embodiment, the first fixing unit 14 of the first housing 1 and the second fixing unit 25 of the second housing 2 are screw holes. The fixing component (not shown) penetrates through the first fixing unit 14 and the second fixing unit 25, so that the first fixing unit 14 and the second fixing unit 25 are secured to each other, and the top plate 13 of the first housing 1 and the second sidewall 24 of the second housing 2 are secured to each other. Preferably but not exclusively, the fixing component is a screw, a bolt, or a clamp. In some other embodiments, the first fixing unit 14 and the second fixing unit 25 are secured to each other by directly aligning and assembling, such as by snap-fit, magnetic attachment, interference fit, or other forms of directly aligning and assembling, but not limited thereto.

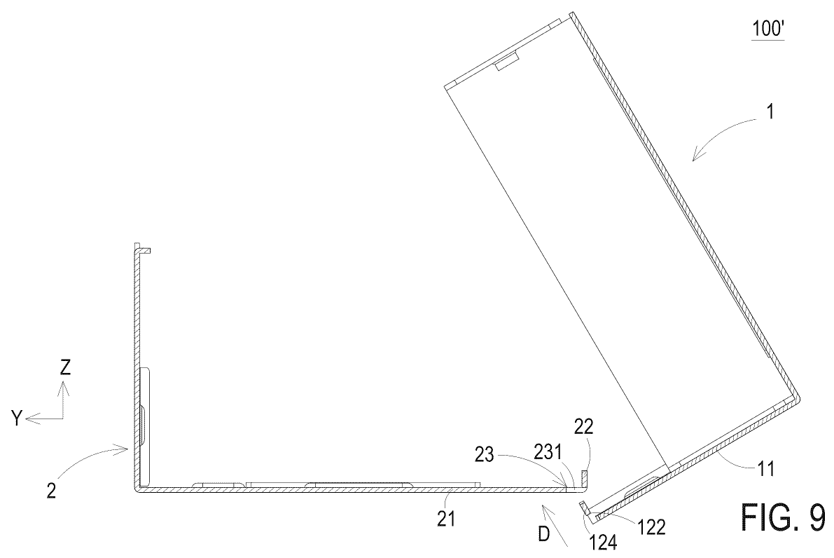

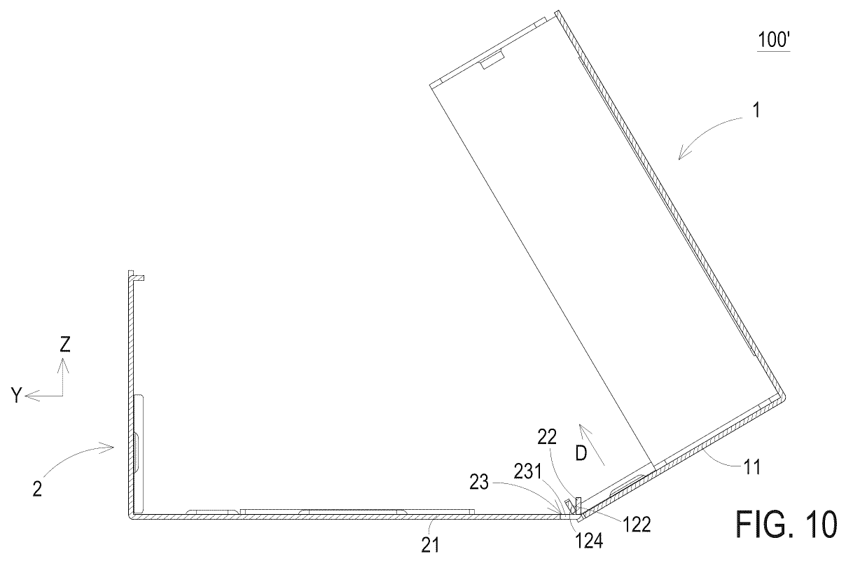

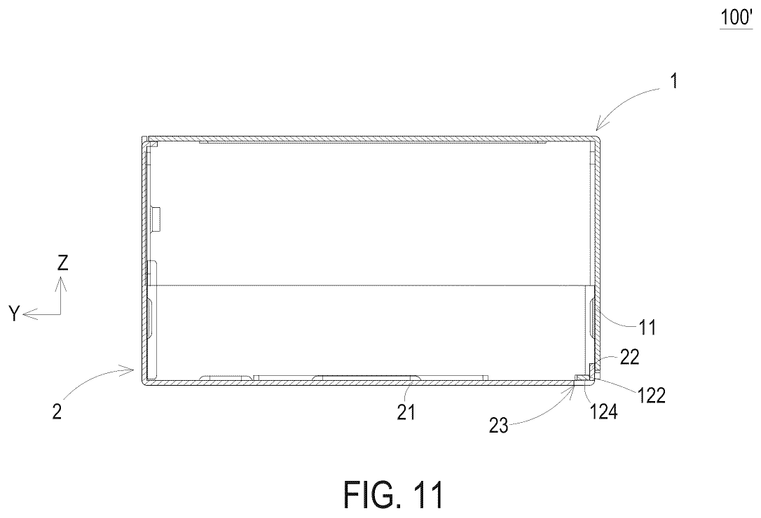

FIG. 9 is a cross-sectional view of a housing assembly according to a variant embodiment, wherein the first housing and the second housing are in a disassembled state, and an angle between a first sidewall of the first housing and a bottom plate of the second housing is greater than 90 degrees. FIG. 10 is a cross-sectional view of the housing assembly of FIG. 9, wherein a buckle portion of the first housing penetrates through a bottom plate opening of the second housing. FIG. 11 is a cross-sectional view of the housing assembly of FIG. 9, wherein the first housing and the second housing are in a latched state. In this variant embodiment, the structure of the housing assembly 100′ is similar to the housing assembly 100 shown in FIG. 1 to FIG. 8, and the same reference numerals indicate the same components and functions. In the present embodiment, the hook members 12 of the first housing 1 of the housing assembly 100′ can be plugged into the corresponding openings 23 of the second housing 2 at various suitable angles. As shown in FIG. 9, the first housing 1 and the second housing 2 are in the disassembled state, and an angle between the first sidewall 11 of the first housing 1 and the bottom plate 21 of the second housing 2 is greater than 90 degrees. When the first housing 1 and the second housing 2 are switched from the disassembled state to the latched state, the first housing 1 moves toward the second housing 2 along a specific direction D, so that at least a part of the buckle portion 122 of each hook member 12 of the first housing 1 is disposed in the bottom plate opening 231 of the second housing 2. Thereafter, the first housing 1 continuously moves toward the second housing 2 along the specific direction D, so that the buckle portion 122 of the first housing 1 penetrates through the bottom plate opening 231 of the second housing 2, as shown in FIG. 10. Finally, the first housing 1 rotates with an extending direction (X-axis direction) of the second parts 124 of the buckle portions 122 of the at least two hook member 12 as an axis, so that the first housing 1 rotates radially toward the second housing 2 until the first sidewall 11 is in contact with the lateral plate 22, thereby forming the latched state, as shown in FIG. 11. In an embodiment, the specific direction D is parallel to the XZ plane, and an angle between the specific direction D and the bottom plate 21 of the second housing 2 is greater than or equal to 0 degree, and less than or equal to 90 degrees, but not limited thereto. Since the hook members 12 of the first housing 1 can be plugged into the corresponding openings 23 of the second housing 2 at various suitable angles, the advantage of enhancing the assembly convenience is achieved.

In an embodiment, when the first housing 1 and the second housing 2 are in the latched state, the first housing 1 can be rotated with the extending direction (X-axis direction) of the second parts 124 of the buckle portions 122 of the at least two hook members 12 as the axis, so that an open space or a closed space is formed between the first housing 1 and the second housing 2 of the housing assembly 100′. Consequently, the advantage of enhancing assembly convenience is achieved. In an embodiment, a rotatable range of an angle of the first housing 1 relative to the second housing 2 is 90 degrees. An angle between the first sidewall 11 of the first housing 1 and the bottom plate 21 of the second housing 2 is greater than or equal to 90 degrees, and less than or equal to 180 degrees, but is not limited thereto.

From above descriptions, the present disclosure provides a housing assembly. By correspondingly assembling the hook members of the first housing with the openings of the second housing, the advantages of preventing housing components from falling off, reducing damage or deformation to the hook members and enhancing the structural stability of the housing assembly are achieved. In addition, since the first housing is rotatably or detachably assembled to the second housing, the advantage of improving assembly convenience is also achieved.

While the disclosure has been described in terms of what is presently considered to be the most practical and preferred embodiments, it is to be understood that the disclosure needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A housing assembly, comprising:
a first housing comprising:
a first sidewall comprising a first sidewall outer surface and a first sidewall inner surface opposite to each other;
at least two hook members, wherein each of the at least two hook members includes a bending portion and a buckle portion, the bending portion is formed by bending a portion of the first sidewall in a direction perpendicular to the first sidewall inner surface, the buckle portion is in connection with an end of the bending portion and comprises a first part and a second part, wherein the first part is in connection with the bending portion, the second part is extending from the first part in a direction parallel to the first sidewall outer surface, and the second part is misaligned with the bending portion, wherein the second parts of the buckle portions of the at least two hook members are extended toward opposite directions, respectively;
a top plate in connection with a first side edge of the first sidewall opposite to the at least two hook members and perpendicular to the first sidewall inner surface; and
a first fixing unit disposed on the top plate; and
a second housing configured to assemble with the first housing and comprising:
a bottom plate;
a lateral plate extending from the bottom plate in a direction perpendicular to the bottom plate;
at least two openings, wherein each of the at least two openings comprises a bottom plate opening and a lateral plate opening, the bottom plate opening penetrates through the bottom plate, the lateral plate opening penetrates through the lateral plate and is in communication with the bottom plate opening, wherein the width of the bottom plate opening is greater than the width of the lateral plate opening, and a blocking portion is formed on a misaligned position of the bottom plate opening and the lateral plate opening;
a second sidewall connected to a side edge of the bottom plate opposite to the lateral plate; and
a second fixing unit disposed on the second sidewall, and configured to align and assemble with the first fixing unit for securing;
wherein each of the at least two hook members of the first housing penetrates through corresponding one of the bottom plate openings of the second housing, the bending portion is accommodated in the lateral plate opening, the second part of each of the at least two hook members is disposed corresponding to the blocking portion, and the first fixing unit and the second fixing unit are aligned and assembled to form a latched state.

2. The housing assembly according to claim 1, wherein the first housing and the second housing are configured to be in one of the latched state and a disassembled state, wherein when the first housing and the second housing are in the disassembled state, the first housing is spaced apart from the second housing, wherein when the first housing and the second housing are switched from the disassembled state to the latched state, the first housing is moved toward the second housing, so that at least a part of the buckle portion of each of the at least two hook members of the first housing is disposed within the corresponding one of the bottom plate openings of the at least two openings of the second housing, wherein the first housing moves in an extension direction parallel to the lateral plate of the second housing, so that each of the at least two hook members of the first housing penetrates through corresponding one of the bottom plate openings and is disposed corresponding to the blocking portion, wherein the bending portion is accommodated in the corresponding lateral plate opening, and the first fixing unit and the second fixing unit are aligned and assembled to form the latched state.

3. The housing assembly according to claim 1, wherein the first housing and the second housing are configured to be in one of the latched state and a disassembled state, wherein an angle between the first sidewall of the first housing and the bottom plate of the second housing is greater than 90 degrees, wherein when the first housing and the second housing are switched from the disassembled state to the latched state, the first housing in the disassembled state moves toward the second housing along a specific direction, so that at least a part of the buckle portion of each of the at least two hook members of the first housing is disposed in the corresponding bottom plate opening of the second housing, wherein the first housing continuously moves toward the second housing along the specific direction, so that the buckle portion of the first housing penetrates through the bottom plate opening of the second housing, wherein the first housing rotates with an extending direction of the second parts of the buckle portions of the at least two hook members as an axis, so that the first housing rotates radially toward the second housing until the first sidewall is in contact with the lateral plate, wherein the first fixing unit and the second fixing unit are aligned and assembled to form the latched state.

4. The housing assembly according to claim 2, wherein when the first housing and the second housing are switched from the latched state to the disassembled state, the first housing in the latched state moves in a direction away from the lateral plate of the second housing, so that the buckle portion of each of the at least two hook members of the first housing is disposed in the bottom plate opening, wherein the first housing moves in a direction away from the bottom plate of the second housing, the buckle portion of each of the at least two hook member of the first housing is separated from the corresponding bottom plate opening of the second housing, and the first housing and the second housing are in the disassembled state.

5. The housing assembly according to claim 1, wherein the bending portion of each of the at least two hook members comprises:
a first connection segment extending from the first sidewall in a direction parallel to the first sidewall outer surface;
a bending segment, wherein an end of the bending segment is in connection with the first connection segment, and the other end of the bending segment is bending from a direction parallel to the first sidewall outer surface toward a direction perpendicular to the first sidewall outer surface; and
a second connection segment, wherein an end of the second connection segment is in connection with the bending segment, and the second connection segment is extending in a direction perpendicular to the first sidewall outer surface, wherein the other end of the second connection segment is in connection with the first part of the buckle portion, wherein the second connection segment detachably matches with the lateral plate opening.

6. The housing assembly according to claim 5, wherein each of the at least two openings of the second housing comprises an opening top surface, a first opening lateral surface, an opening bottom surface, a second opening lateral surface, a blocking portion bottom surface and a blocking portion lateral surface, wherein the opening top surface, the first opening lateral surface, the opening bottom surface, the second opening lateral surface, the blocking portion bottom surface and the blocking portion lateral surface of each of the at least two openings are sequentially connected, and surround the opening, wherein the blocking portion lateral surface, the opening top surface and a part of the first opening lateral surface of each of the at least two openings surround the lateral plate opening, wherein a part of the first opening lateral surface, the opening bottom surface, the second opening lateral surface and the blocking portion bottom surface of each of the at least two openings surround the bottom plate opening, wherein the second connection segment of the bending portion of each of the at least two hook member is disposed between the first opening lateral surface and the blocking portion lateral surface, wherein the width of the second connection segment is less than the distance between the first opening lateral surface and the blocking portion lateral surface.

7. The housing assembly according to claim 5, wherein the first connection segment of the bending portion of each of the at least two hook members has a first connection segment inner surface, the first connection segment inner surface is in connection between the first sidewall inner surface and the bending segment, and the first connection segment inner surface and the first sidewall inner surface are coplanar, wherein the first connection segment inner surface and a part of the first sidewall inner surface are in contact with the lateral plate, wherein the second part of the buckle portion of each of the at least two hook members has a second part lateral surface, the second part lateral surface is in connection with the second connection segment of the bending portion and is parallel to the first sidewall inner surface, wherein the second part lateral surface is in contact with the blocking portion.

8. The housing assembly according to claim 1, wherein when the first housing and the second housing are in the latched state, the first housing is rotated with an extending direction of the second parts of the buckle portions of the at least two hook members as the axis, so that an open space or a closed space is formed between the first housing and the second housing, wherein a rotatable range of an angle of the first housing relative to the second housing is 90 degrees, wherein an angle between the first sidewall of the first housing and the bottom plate of the second housing is greater than or equal to 90 degrees, and less than or equal to 180 degrees.

9. The housing assembly according to claim 1, wherein the at least two hook members and the first sidewall are integrally formed into one piece bent structure, wherein the first sidewall comprises at least two recesses, the at least two recesses are inwardly recessed from a second side edge of the first sidewall, respectively, and each of the at least two hook members is connection with corresponding one of the at least two recesses.

10. The housing assembly according to claim 1, wherein when the first housing and the second housing are in the latched state, the top plate of the first housing is in contact with the second sidewall of the second housing, so that the top plate, the first sidewall, the bottom plate, and the second sidewall collectively define an accommodation space, wherein the housing assembly comprises at least one fixing component, the fixing component is configured to secure the top plate of the first housing and the second sidewall of the second housing.
